(19) United States
(12) Patent Application Publication
(10) Pub. No.: US 2009/0227093 A1
(43) Pub. Date: Sep. 10, 2009

(54) Patterning During Film Growth

(75) Inventors: William J. Schaff, Ithaca, NY (US); Xiaodong Chen, Ithaca, NY (US)

Correspondence Address: SCHWEGMAN, LUNDBERG & WOESSNER, P.A., P.O. BOX 2938, MINNEAPOLIS, MN, 55402, US

(73) Assignee: Cornell Research Foundation, Inc, Ithaca, NY (US)

(21) Appl. No.: 12/223,944

(22) PCT Filed: Feb. 16, 2007
(86) PCT No.: PCT/US07/04068

§ 371 Date: Nov. 6, 2008

Related U.S. Application Data
(60) Provisional application No. 60/774,455, filed on Feb. 17, 2006.

(51) Int. Cl. H01L 21/20; C23C 14/30

(52) U.S. Cl. 438/509; 118/723 R; 257/E21.09; 257/E21.347

(57) ABSTRACT

The growing surface of a material such as InGaN is exposed to a small diameter laser beam that is directed to controlled locations, such as by scanning mirrors. Material characteristics may be modified at the points of exposure. In one embodiment, mole fraction of selected material is reduced where laser exposure takes place. In one embodiment, the material is grown in a MBE or CVD chamber.

### GOVERNMENT FUNDING

The invention described herein was made with U.S. Government support under Grant Number F49620-03-1-0330 awarded by AFOSR. The United States Government has certain rights in the invention.

### BACKGROUND

In semiconductor fabrication processes, modification of the properties of materials on a local scale is traditionally performed through processes that follow the step of materials growth. Lithography using photoresist typically defines patterns for etching or deposition. Patterning of semiconductor device features is performed for defining active devices and interconnects. Both electrical and optical devices and interconnects are created by removal of materials and addition of other metal, semiconductor or dielectric materials.

### BRIEF DESCRIPTION OF THE DRAWINGS

FIG. 1 is a block schematic view of a modified MBE machine that allows writing of patterns by laser during growth of a layer according to an example embodiment.

FIG. 2 is a block schematic view of a laser source for the machine of FIG. 1 according to an example embodiment.

FIG. 3 is a block schematic view of a laser writing system for the machine of FIG. 1 according to an example embodiment.

FIGS. 4A and 4B are graphs of spot size and optical flux density as a function of distance according to an example embodiment.

FIG. 5 is a computer aided design (CAD) layout of exposure patterns according to an example embodiment.

FIG. 6 illustrates a further exposure pattern and layer structure according to an example embodiment.

FIG. 7 is a scanning electron microscopy image made in secondary electron emission mode of a formed layer based on the exposure pattern of FIG. 6.

FIG. 8 illustrates an In composition profile determined by wavelength dispersive spectroscopy analysis of the layer formed based on the exposure pattern of FIG. 6 superimposed on a back scattered electron image.

FIG. 9 illustrates line scan height variation across a written region of a layer formed based on the exposure pattern of FIG. 6.

FIG. 10 illustrates photoluminescence of regions where exposure did and did not take place during growth of a layer according to an example embodiment.

FIG. 11 illustrates photoluminescence intensity as a function of a position along a line path according to an example embodiment.

FIG. 12 illustrates photoluminescence intensity as a function of multiple line paths according to an example embodiment where dark features are highest intensity.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description is, therefore, not to be taken in a limited sense, and the scope of the present invention is defined by the appended claims.

The growing surface of a material is exposed to localized heating or radiation, such as by a small diameter laser beam that is directed to controlled locations, such as by scanning mirrors. Material properties or characteristics may be modified at the points of exposure. A modified molecular beam epitaxy machine with laser writing capabilities is first described, followed by a description of a process and example of using the machine. Alternative embodiments are also described.

In one embodiment, the growing surface of a material such as InGaN is exposed to a small diameter laser beam that is directed to controlled locations, such as by scanning mirrors. Material characteristics may be modified at the points of exposure. In one embodiment, indium mole fraction of selected material is reduced where laser exposure takes place.

In a further embodiment, indium diffuses away from exposed regions to create smaller In fraction under exposure and a larger In fraction immediately adjacent to an exposed region. Thickness variation appears consistent with mass transport indicating that minimal indium evaporates. The effect of local laser illumination or thermal heating appears to enhance surface diffusion while not causing ablation or evaporation under the conditions studied.

The exposure of a growing material to focused radiation may have many different utilities.

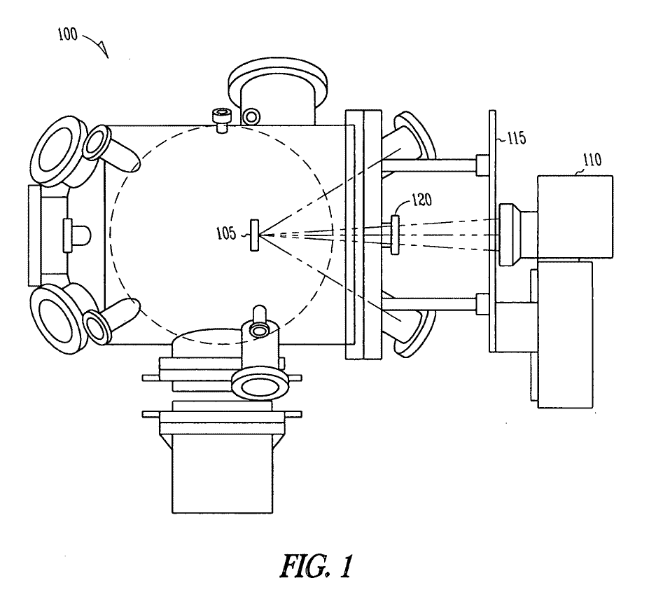

FIG. 1 illustrates a modified molecular beam epitaxy machine 100 that facilitates patterning a substrate 105 during growth. A beam steering system 110 is used to project a laser, or other focused radiation onto the substrate in a controlled manner to expose selected patterns during growth. Lateral composition control of the material being grown may be provided, or enhanced photoluminescence efficiency. The laser enters the MBE machine through a vacuum window 115, then passes through a viewport 120. The viewport 120 may be heated to prevent materials from condensing on the window that would degrade optical transmission strength.

The MBE machine may have a gas bonnet removed, and a shutter front mounting plate and shutter arms modified to be as close as possible to a source shroud without impeding furnace removal. A rear mounting plate may also be moved to permit an optical head to fit between mounting plates. Pneumatic shutter arms may also be shortened to permit a laser writing head to have a desired lens to wafer spacing. In one embodiment, the spacing is approximately 19.8 inches.

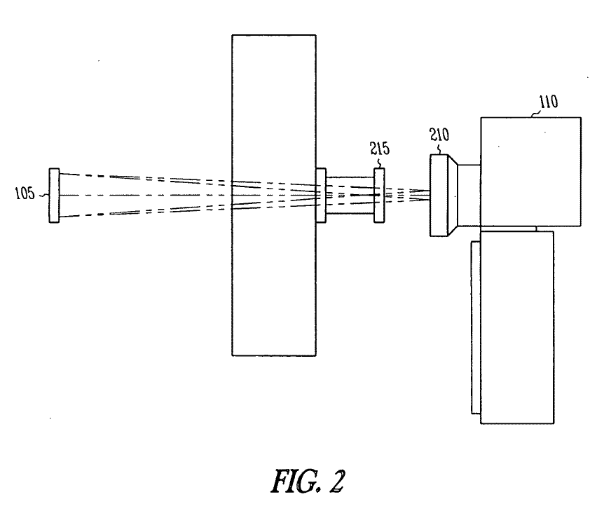

A second view illustrates optical beam paths, and challenges to obstructions in FIG. 2. It shows a lens 210 to optical viewport opening 215 distance of approximately three inches. Wafer illumination area is a function of lens focal length, wafer distance, size of hot window restrictions, and distance to hot window restriction. In one particular MBE machine, these factors provide the ability to write within a two inch wafer area. There are tradeoffs in spot coverage and spot size dictated by opening size, beam size before focus, distance to wafer and f-theta lens 210 availability. The f-theta lens 210 is corrected to provide flat surface field coverage. This lens is widely used in laser machining systems where the largest diameter exposure field with no change in beam size is desired. Only a few commercial f-theta focal lengths are available commercially. In one embodiment, the system 100 uses a 480 mm focal length f-theta lens. Other lenses and method of creating a spot of radiation on the substrate during growth may also be used.

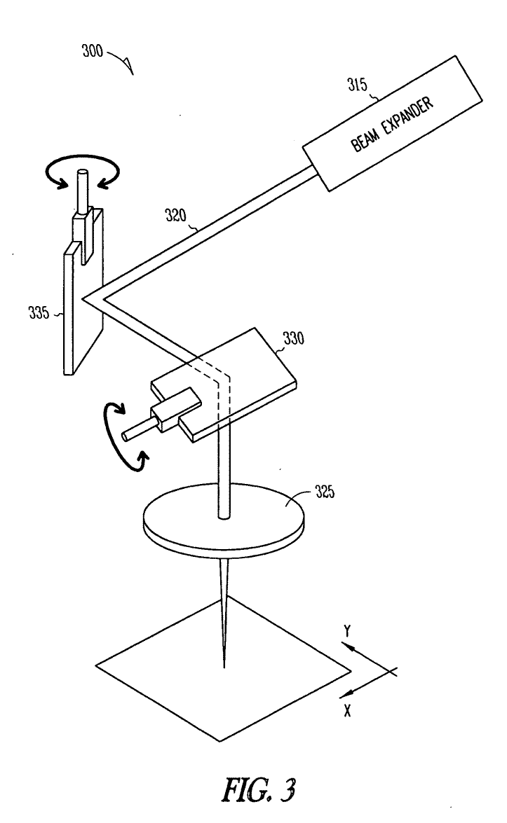

FIG. 3 is a schematic representation of a beam expander and mirror arrangement 300 for patterning substrates during growth. A laser 310 provides a beam that is expanded in diameter from a small size (fractions of a mm) up to several mm by a beam expander 315. The laser beam may be provided by an optical fiber in one embodiment. The expanded beam is focused by one or more lenses 320 onto a substrate 325. One or more mirrors 330, 335 provide x,y positioning of the expanded beam for controlled patterning of the substrate during growth of the substrate. The mirrors are coupled to servos for rotating the mirrors to control the beam location on the substrate 325. Commercially available laser writing control tools, such as WinLase Professional, are available, and may be used to control the position of the laser spot on the substrate. Writing speed and laser power can be set for each line, and the line speed may be significantly varied, such as from 5 to 256,410 mm/sec or other speeds as desired.

In one embodiment the expanded beam is focused prior to mirror deflection instead of before mirror deflection. Focusing after mirror deflection a shown in FIG. 3 results in a lower power density on the mirrors and greater freedom from mirror damage. Such a system may require large mirrors (>10 mm) to handle a 10 mm diameter beam. When scaling up the beam diameter, larger diameter mirrors may be needed. The larger mirrors require larger motors because of their larger mass. A practical trade-off between mirror diameter and scanning speed then comes into play.

In general:

$$s = \frac{λ f}{d}$$

s=spot size
λ=laser wavelength
f=focal length of lens
d=beam expanded diameter

On the following pages, trade-offs in these parameters are described with discussion of comparison to one implementation on a machine. Results may vary with the use of other machines and different embodiments.

All of the comparisons and analysis assume two mirrors for x and y positioning. It is feasible to consider much larger effective mirrors and beam diameter by moving from servo driven mirrors to micro-mirror arrays. An example of a micro-mirror are the Texas Instruments arrays that are used for digital light projection (DLP) in computer light projectors for auditoriums/conference rooms and some modern large screen TVs.

Various embodiments are not limited to just one wavelength. Any form of high intensity light that can be directed may be suitable, if it is high enough power. In one embodiment, a digital projector projecting through a focusing lens to make small features may be used. In one embodiment, a $50,000 laser may be replaced with a $1,000 projector and $1,000 lens. In a further embodiment, an average power of 10 W is used, but with much higher peak power during the pulses. In a further embodiment, a few watts from a DLP may be extracted. Other variations include building the light projection inside the MBE system for closer spacing to the wafer. In one embodiment, a heated lens may be used to avoid spurious deposition. Closer spacing to the wafer could occur for gas sources rather than thermal sources. Gas source MBE is a fairly common technique. OMVPE reactors have much closer access to the wafer from the outside, so this technique could already enable smaller features. Another approach for very large areas (multiple wafers or very large wafers) involves writing on a fraction of the wafer area at a time. Shutters and exposure conditions may be synchronized to essentially step and repeat the process in different areas at different times.

In a further embodiment, wafers may be written during substrate rotation, and may also take into account mechanical backlash. Substrate wobble effects can be minimized by synchronizing optical excitation and measurements with substrate position. Since each wafer mounting may introduce a unique wobble, an optical encoder may be used to track the substrate position, and allow the synchronization. In a further embodiment, the substrate may be mounted on an x-y raster system, which can further increase the area of the substrate that can be written.

In-situ patterning during materials deposition can replace one or more processing steps and lead to a cost savings in structure fabrication. New structures can be constructed in-situ during epitaxy with a directed radiation beam that cannot be created through traditional ex-situ processing.

Spot size is a fairly linear function of wavelength for a predetermined geometry in the embodiments described above. For example, a 59 μm spot size could be 12 μm by changing from a YAG wavelength of 1.06 μm to a quadruped YAG of 0.254 μm.

Spot size also appears to be a fairly linear function of focal length of the lens using the same laser wavelength. If the MBE machine geometry is changed such that a writing head lens is closer to the wafer surface, beam diameter may be made smaller than 5 μm if spacing smaller than 50 mm may be achieved. This may be easier to do with gas source machines. In the particular geometry described above, the spot size varies from about 10 μm to 50 μm with corresponding lens to wafer spacing of approximately 100 mm to 500 mm.

The spot size may also vary with expanded beam diameter. The disadvantage with larger beam diameters is slower mirror motion because of larger mass mirrors, and the need for a larger opening for the beam to pass through when it enters the machine. In one embodiment, a one inch opening makes it possible to write to a two inch diameter area on the wafer. These parameters may easily change with different embodiments. The spot size may also vary with changes in lens to wafer distance, with shorter distances generally corresponding to smaller spot sizes. One alternative to increasing the area of the wafer that can be written is to increase the size of the opening into the chamber.

In one embodiment, the wavelength of the laser is chosen to be larger than the bandgap of the material. Pulses of laser may be used to obtain short bursts of higher power. Pulsing is not required if using lasers of sufficient power for the desired effects on the material being grown. In one embodiment, the emission energy of the laser may be shorter than the bandgap of the material being grown. Very short pulses, such as pulses in the femtosecond range may be used. Such very short pulses may create a large electric field, and cause structural changes in the material being grown. The exact mechanism or cause of the structural changes may not be fully understood, and so any explanations of such mechanisms or causes are not being represented as fact.

The method of patterning growing material with focused radiation may be performed on many different materials and many different methods of growing the materials. In addition to MBE methods of growing material, other methods may include chemical vapor deposition (CVD), such as MOCVD, and HPCVD. Different types of growth of material include epitaxial, non-crystalline, polycrystalline and monocrystalline growths. Further materials which may be grown include III-nitrides, various semiconductors, non-semiconductors, superconductors, ceramics and plastics, or other materials that can be grown using many different growth techniques.

In one embodiment, directed laser heating is applied to local regions during the growth of InₓGa₁₋ₓN by molecular beam epitaxy (MBE). The effect of local heating is to alter the composition of the InₓGa₁₋ₓN alloy, both in the exposed regions, and immediately adjacent to them. In one embodiment, there are at least three different In mole fractions that result from this exposure: 1) x=0.75 under exposure, 2) x=0.85 adjacent to exposure, 3) x=0.81 uniform composition away from exposed regions during a nominal 78 nm deposition on a 540 nm thick buffer. Exposed regions are 20 nm thinner and adjacent regions are 20 nm thicker than equilibrium values which indicates a diffusion of In away from hot regions towards cooler regions. Other process conditions may produce features that are buried within further deposition. Three-dimensional patterning of In mole fraction may be performed such as by varying the local region size and/or location while growth is occurring.

Direct write composition patterning provides a new way to create structures which cannot be made by etching and redeposition, such as the structures that are described herein. It is shown that structures such as optical waveguides can be created from in-situ composition control in regions directed by a 50 μm diameter scanned laser beam. Since the electrical conductivity of InGaN is a strong function of mole fraction, it is expected that the written features will also be useful as electrical interconnects.

One addition feature of in-situ direct write patterning is the enhancement of photoluminescence efficiency. PL (photoluminescence) efficiency increases by a factor of 7 compared to non-exposed regions. Brief experiments to understand the origin of PL enhancement indicate that the dominant effect might not be improved radiative efficiency due to high temperature annealing (deduced through comparisons of front and back side photoluminescence), but likely comes from surface morphology modification in the exposed regions. Modification of surface morphology has become an important feature in obtaining higher LED output power in GaN based LEDs. Surface morphologies can be created which are more effective at extracting light compared to a flat surface which is much less efficient. It should be noted that surfaces that are more suitable for extracting light can also be made more efficient for collecting light. This characteristic is very important for solar cells. This new technology will be very important for multiple junction solar cells. Since the interface between each material in the multiple junctions will act to reflect light and reduce capture efficiency, the laser direct write patterning will offer a way to improve efficiency of solar cells by optimizing the optical transmission properties of multiple junction structures.

Laser direct write has also been applied to the growth of AlN on Si. A 100 nm AlN layer is first deposited on Si. Since it is transparent to the IR laser light, the laser does not heat AlN, but does heat Si below. Ablation of the AlN above Si takes place, accompanied by etching of more than 1 micron of Si. AlN is then grown back into the exposed region. This type of structure has applications as an optical waveguide for interconnects.

Grayscale features are demonstrated by laser direct write. A pattern with such subtle effects that are not visible by secondary electron microscopy can have strongly defined composition features as detected by back-scattered electron imaging. Grayscale variations in compositions have applications to mirrors, lenses and other optical behavior. As an example, it would become possible to integrate a lens for a vertical cavity laser directly on top of the laser for collimation of light during the wafer growth.

A major advantage that direct write during epitaxy has over etch and regrowth techniques is that the wafer surface is never exposed to contaminates from air or photoresists. The composition control occurs without contamination and the undesirable electrical and optical properties that can result.

Another potential application would be to create different polarization crystal orientation through laser direct write. It would be possible to prevent or permit different polarization materials to be created through the process demonstrated. These patterned polarization materials are valuable for creating large optical non-linearities for switching and laser energy multipliers. This capability could be performed in semiconductors or ceramics such as lithium tantalate or other polar materials. It would be possible to create integrated lasers and switches or multipliers in a manner which cannot be accomplished with etch and regrowth techniques.

A further application is to create control of dopants which are difficult to control at high vapor pressures. Since the laser can heat local regions and cause atoms to migrate and not evaporate, it might be possible to get greater control of incorporation of atoms such as Mg, Mn and Zn in nitride semiconductors in ways not possible with 2D growth.

The technique has been demonstrated utilizing III-Nitride semiconductors (and Si substrates), but is generally applicable to all semiconductor materials systems. It is easy to envision SiGe composition control as well as the telecommunications semiconductors such as GaInAs, AlGaInP, etc. The commercial opportunities in these established systems will be much stronger initially than for InGaN which is not commercially utilized in the compositions studied so far. A shorter wavelength laser would be suitable for such materials as GaAs, GaP, GaN and other larger bandgap semiconductors. Extraction of light more efficiently from LEDs in that material system would be a commercial advantage.

Direct write composition patterning provides more than simply saving the cost of a lithography step, it permits new structures to be built which cannot be made by any other technique, and advances the performance of existing structures, in areas such as light extraction efficiency. The technique will have wide spread applications that are not yet conceived by designers who have only had 2-D tools available in the past. Epitaxy for simple 2-D wafer fabrication is expected to be displaced by the 3-D techniques shown.

In one embodiment, simultaneous laser patterning is performed during epitaxy. Composition patterning and photoluminescence improvement are two effects that have been observed by the use of focused radiation during growth. Further applications may include all opto-electronics for semiconductors and other materials, creation of new two and three dimensional structures, control of bulk and surface conductivity, Fermi level modification, modification of III/V ratios, control of composition and deposition rates, etching, and mass transport among others.

In one experiment, using fairly old equipment that may be modified as described above, InGaN was grown by molecular beam epitaxy using thermal evaporation sources of In, Ga and Al. Nitrogen was supplied from low purity liquid nitrogen boil-off and passes through three stages of particle and oxygen/moisture removal. Resin filters preceding a mass flow controller, are followed by a getter filter at the nitrogen source. It should be noted that this is a documentation of what was done, and it not meant to be limiting in any manner unless specifically claimed.

The growth chamber was a 3-inch substrate capable Varian GEN II previously used for 9 years of arsenide/phosphide growth prior to 8 years of nitride growth. Arsenic, phosphorous and arsenic oxide residues were still visible and may be seen on the residual gas analyzer during bakeout and substrate heating. GaN and InN with SIMs background detection limit (˜5×10¹⁶ cm⁻³) levels of oxygen and carbon are routinely measured for layers of one micron or more of thickness. This is not unexpected for GaN where high substrate temperature (˜750° C.) enhances oxygen desorption while InN (˜500° C.) would be expected to be more sensitive to unintentional oxygen background. Oxygen might be minimized as the result of aggressive techniques to remove moisture and oxygen from the MBE environment. During a typical bakeout, the machine temperature is raised to 150° C. during the first day. On the second day, the substrate heater power is raised to 425 W over 10 hours which produces a thermocouple reading of about 1000° C. This step depletes contamination from the substrate heater assembly, and further raises the machine temperature. After one more day of bake, cell temperatures were raised to 400° C. for the remaining day.

Sapphire substrates are metalized on the lapped backside with sputtered tungsten at about 1 micron thickness. Wafers are loaded with no surface treatment into a preparation chamber for baking at 300° C. in UHV. Temperature changes are made slowly to avoid sapphire wafer shattering due to thermal stress. The substrate is loaded in the growth chamber for exposure to the RF plasma source. A 45 minute 500 W exposure at 200° C. assists in changing the sapphire surface into one that presumably has some AlN surface structure, although RHEED observations do not consistently indicate a change. The wafer temperature is then ramped to 800° C. for AlN growth. When a GaN buffer is used, AlN thickness is approximately 300 nm prior to 750° C. growth of GaN.

A Veeco RF plasma source was used to generate active and atomic nitrogen that incorporates in nitride layers at growth rates near 0.5 microns/hour. Plasma power is 400 W and nitrogen flow rates are 0.8 to 1 sccm. Detailed comparisons of InN characteristics with RF source conditions are not performed; correlation is not casually apparent. The substrate thermocouple temperature was close to 530° C. for InGaN and was not regulated in feedback. DC voltage applied to the substrate heater was held at constant values during AlN, GaN or InN growth. This mode leads to stable substrate temperature as observed by RHEED patterns and pyrometer, especially for high temperature GaN and AlN growth. AlN buffers are grown near 800° C. and GaN is near 750° C. by pyrometer measurements.

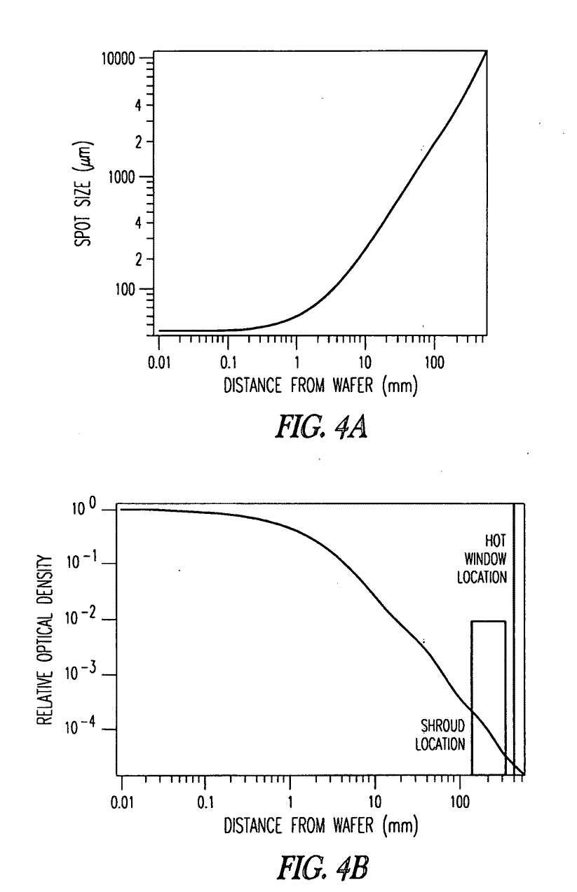

FIGS. 4A and 4B show simple calculations of beam size at different distances from the wafer. In this embodiment, the laser to wafer distance was approximately 480 mm. FIGS. 4A and 4B show that just 3 mm error in placement doubles the beam size (and lowers the beam intensity by a factor of 4). Some error in getting the laser tool lens and wafer perfectly flat is routinely encountered in initial tests. It can be seen in features on the patterned wafers that beam intensity can be different across a wafer and cause different effects. This is easily solved with careful positioning, but has presented the initial ability to change intensity with position through different focal lengths.

In a further embodiment, a mechanized mount may be provided to move the laser head closer and farther from the wafer to effect large changes in focus, therefore optical density. Small variations in distance may be useful to obtain a wider dynamic range in laser power density.

The above example was performed using a laser with the following characteristics:
1063 nm laser wavelength chosen for this program
   Lower laser cost for equivalent optical power density
   Optics are coated for 1064 and 532 nm operation to permit future 532 nm operation
   Sub-bandgap wavelength for some of the GaInN alloy range to permit non-absorbing epi windows
IPG Photonics Pulsed Fiber Laser
Model YLP-0.5/100/20
10 W average power
   0.5 mJ pulse energy
   20 KHz, 100 ns
10 mm beam diameter entering focus lens
50 μm beam diameter at wafer

FIG. 5 shows an example CAD pattern that can be written. Lines are specified by laser power and scan speed in addition to size and position. Different regions are specified to be written at different regions of layer growth, and any line can be written at any point during the growth sequence. Features can be written and buried in the growing layer. This example makes outer patterns as a first level that only occur during the first few minutes of growth. Dark features are written at the first level, while lighter features are written later in the growth.

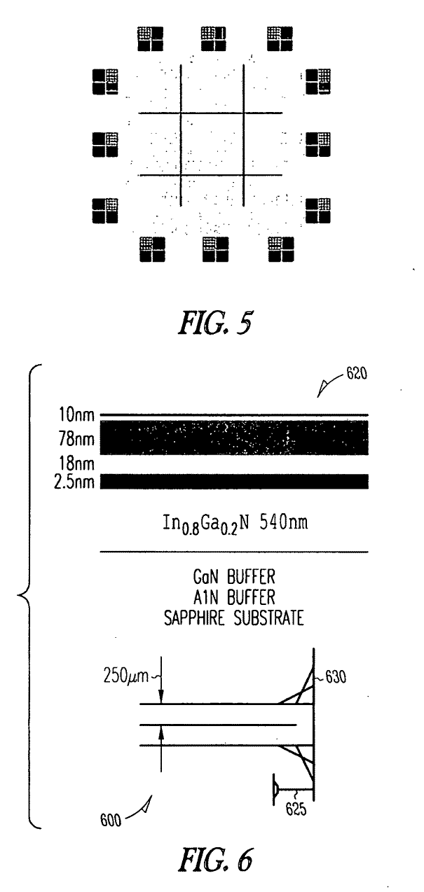

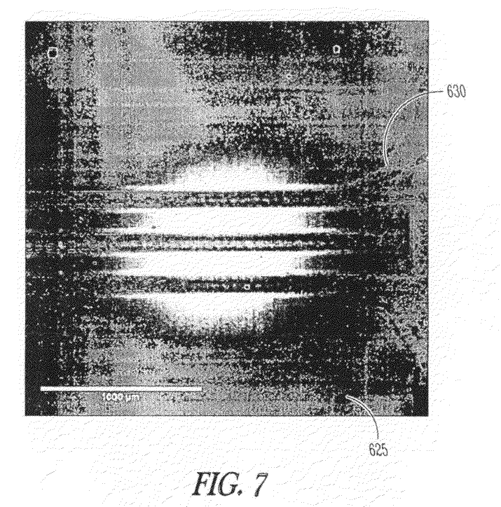

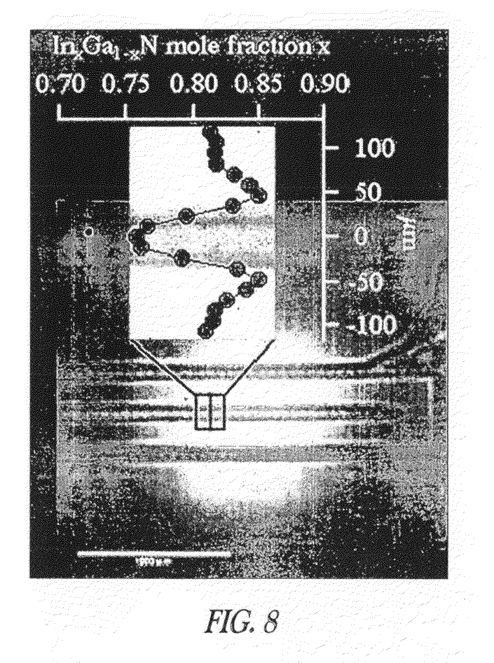

FIG. 6 shows CAD pattern 600 and layer structure 620 that illustrates various aspects of the process. Features are written during different depths of material deposition. Some features 625 are written just a few times and then buried with further deposition. Other features 630 are written more often and can be seen more prominently in the SEM image of FIG. 7.

FIG. 8 is a quantitative measurement of the In composition change. It shows In has moved from the patterned areas out to cooler areas. The absolute numbers for a wavelength dispersive spectroscopy (WDS) analysis are only a lower limit to the actual amount of In composition change occurring near the surface. The penetration depth of the beam is much deeper than the region where surface diffusion takes place. It is likely that the minimum In content is much smaller than 75% in the written region and much higher than 85% in the surrounding region. This may be measured with greater accuracy with scanning Auger electron spectroscopy system.

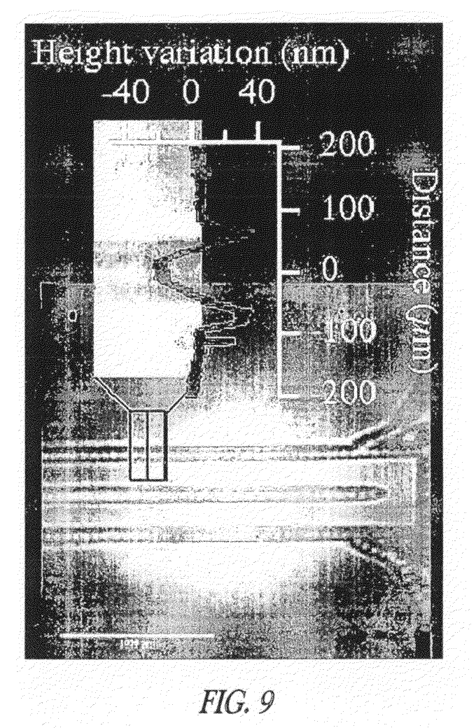

FIG. 9 shows height variation where laser writing has occurred. The laser exposure does not appear to be evaporating material away in any form of laser ablation. The wafer is undergoing local heating under the laser beam and causing increased surface diffusion of In towards non-illuminated, cooler regions. By eye, it appears that the In piling up in cooler regions is the same amount of integrated material that has moved out of the exposed region. This is a much more subtle effect than simply blasting material away in an etching mode. This effect should also be seen in materials such as GaInAs, AlGaAs, GaInN, AlGaN, GaInP, AlInP with appropriate laser wavelength and exposure conditions. Similar effects may occur in further materials.

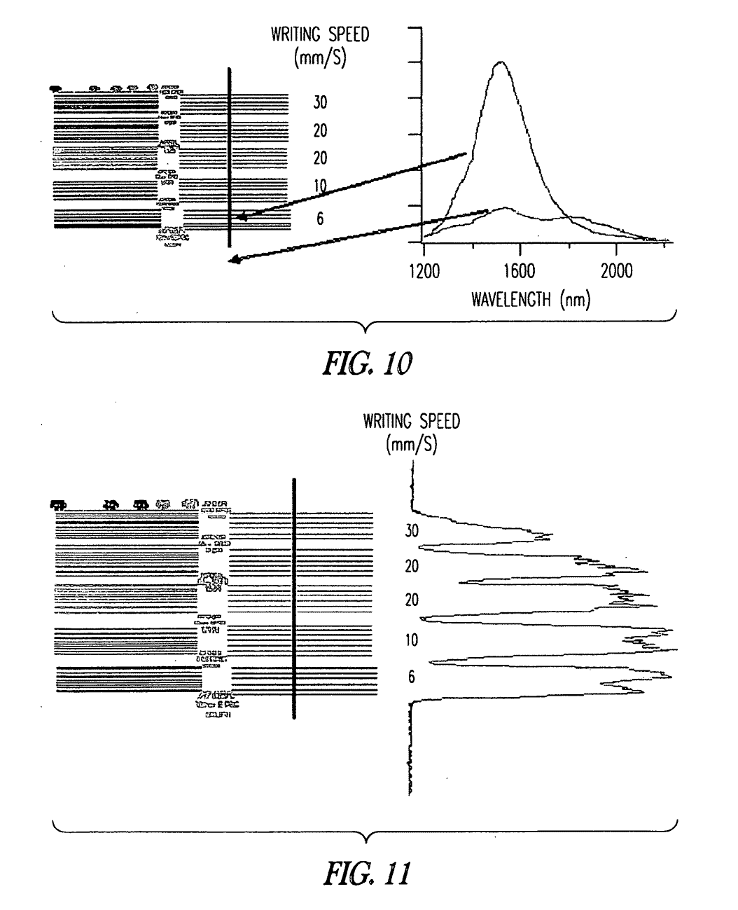

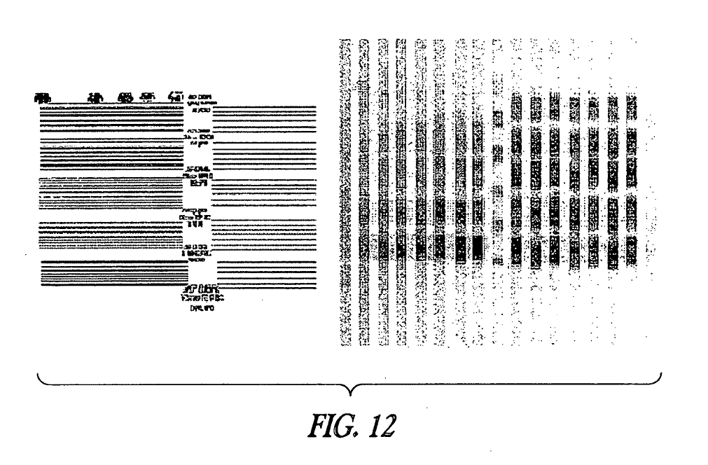

FIG. 10 shows photoluminescence (PL) improvement where laser writing occurred. This is shown in more detail in line scans (FIGS. 11 and 12) to give an easily understood view of how reproducible this effect is—it is not a “lucky” behavior of just 2 places on the wafer, but thousands of points go into these images. The increase in PL intensity is dramatic. 2-D growth provides no control to create this large of an increase. 2D wafers may have minor variations in efficiency across a wide parameter space of growth conditions. Obtaining this large increase as a result of laser exposure was completely unexpected.

Subtle composition may also be obtained. Gray scale lithography is being developed in the lithography world for creating structures such as Fresnel lenses for optical signal routing. The exposure during growth methodology described herein may have considerable advantage over using different resist profiles to create height profiles in etched structures. Height and composition may be controlled in ways that give more flexibility in lens and optical transmission line design. Again, this can be applied outside of just integrated semiconductor optoelectronics, and is already a major new tool for the existing technologies.

It is envisioned that many new applications will arise due to the demonstrated ability to affect growth during growth by exposing to focused radiation. An entire professional generation has been trained in 2D approaches to problems. The ability to provide 3-D capabilities should be very valuable once features are created with this added dimension.

1. A method comprising:
growing a layer using molecular beam epitaxy or chemical vapor deposition; and
exposing selected portions of the layer with radiation while it is being formed.

2. The method of claim 1 wherein the layer comprises a III nitride, semiconductor, plastic or ceramic.

3. The method of claim 1 wherein the layer comprises InGaN.

4. The method of claim 1 wherein a laser beam is used to expose selected portions of the layer.

5. The method of claim 1 and further comprising controlling scanning mirrors to create localized exposure by laser.

6. The method of claim 5 wherein the layer comprises InₓGa₁₋ₓN.

7. The method of claim 5 wherein the scanning mirrors provide x,y control of a laser exposure spot on the layer.

8. The method of claim 7 wherein the speed of the exposure spot may be varied between approximately 5 to 256,410 mm/second.

9. The method of claim 7 wherein the size of the exposure spot on the layer is approximately 50 μm or less.

10. The method of claim 5 wherein the laser is pulsed.

12. The method of claim 10 wherein the laser is pulsed in the femtosecond range.

13. The method of claim 5 wherein the laser has an emission energy greater than the bandgap of the material being formed.

14. The method of claim 1 wherein the exposed portions exhibit one or more of the characteristics comprising varied mole fraction, grayscale features, photoluminescence, and optical non-linearities.

15. A method comprising:
growing a layer in a chamber; and
exposing selected portions of the layer with a laser beam spot while it is being formed.

16. The method of claim 15 wherein the location of the laser beam spot on the layer being formed is controlled to create desired three dimensional features in the layer.

17. The method of claim 16 wherein a set of mirrors is used to control the location of the laser beam spot.

18. The method of claim 17 wherein the mirrors direct the laser beam from outside of the chamber through a viewing port of the chamber.

19. A system for creating three dimensional characteristics in a layer of material being grown within a growth chamber on a substrate, the system comprising:
a laser source that provides a laser beam;
a lens for focusing the laser beam into a spot on the layer being grown; and
a set of mirrors positioned to receive the laser beam from the laser source and for controlling the position of the laser beam spot on the layer being grown.

20. The system of claim 19 wherein the system is positionable outside of the growth chamber to direct the laser beam through a window and onto the layer being grown.

21. The system of claim 19 wherein the laser source comprises an optical fiber, and the system further comprises a beam expander coupled to the optical fiber for providing the laser beam.

22. The system of claim 21 wherein the lens is an f-theta lens positioned between the beam expander and the lens.
